(19) United States
(12) Patent Application Publication
(10) Pub. No.: US 2014/0167243 A1
(43) Pub. Date: Jun. 19, 2014

(54) SEMICONDUCTOR PACKAGES USING A CHIP CONSTRAINT MEANS

(71) Applicant: Yuci Shen, Cupertino, CA (US)

(72) Inventor: Yuci Shen, Cupertino, CA (US)

(21) Appl. No.: 13/712,977

(22) Filed: Dec. 13, 2012

(51) Int. Cl. H01L 23/04

(52) U.S. Cl. CPC H01L 23/04
USPC 257/692

(57) ABSTRACT

A semiconductor chip package using a chip constraint means is provided in the invention. The root cause for the warpage and stress of a semiconductor chip package under a temperature change is the CTE mismatch between the chip and substrate. The current inventive concept is to reduce the CTE mismatch by using a chip constraint means to constrain the thermal deformation of the chip. In one preferred embodiment, the chip constraint means comprises a chip constraint ring surrounding and bonding to the chip. In another preferred embodiment, the chip constraint means further comprises a chip constraint lid covering and bonding to the chip as well as bonding to the chip constraint ring. The overall CTE of the chip and the chip constraint means is to be relatively high when using a high CTE and high modulus of chip constraint means, reducing the warpage and stress of a flip chip package.

### TECHNICAL FIELD OF THE INVENTION

The present invention generally relates to semiconductor chip packages. The present invention particularly relates to flip chip packages using a chip constraint means for reducing the warpage and stress of the flip chip packages.

### BACKGROUND OF THE INVENTION

Flip Chip interconnect technology is extensively used for packaging semiconductor devices because of its capability for accommodating very high pin count per area. The very common semiconductor packages using flip chip interconnect technology includes flip chip packages. A flip chip package primarily comprises a semiconductor chip (also called a die) and a substrate, wherein the chip having electrically conductive bumps such as solder bumps or cu pillar solder bumps on its active surface is flipped and attached on the top surface of the substrate. An underfill material is usually dispensed into the gap between the chip and the substrate through a capillary force to protect solder bumps. Flip chip packages include FCBGA (flip chip ball grid array) packages, FCPGA (flip chip pin grid array) packages and FCLGA (flip chip land grid array) packages, depending on the type of electric contacts on the bottom surface of the substrate of the flip chip packages. FCBGA, FCPGA and FCLGA packages have a plurality of solder balls, pins and electric lands on the bottom surface of the substrate separately. A large warpage is a big issue for flip chip packages using an organic substrate, especially for flip chip packages with a big substrate size and big chip size. To control the warpage of flip chip packages, a ring type of stiffener or a hat type of lid is attached on the substrate of prior arts. When using the conventional stiffener ring or lid to reduce the warpage of flip chip packages, the stress level inside flip chip packages is usually increased, leading to some stress-caused failure issues.

For a flip chip package using an organic substrate, the CTE (coefficient of thermal expansion) of the substrate is about 15 ppm, while the CTE of silicon chip is about 2.6 ppm. The big CTE mismatch between the chip and substrate is the root cause for such issues of the flip chip package as large warpage, dielectric layer cracking, bump bridging and bump cracking in its manufacture, application or reliability test.

There are efforts ongoing to reduce the warpage as well as to improve the reliability of flip chip packages. For example, some type of clips are described to reduce the warpage by clamping the substrate or holding the chip onto the substrate when dispensing and curing an underfill material of prior arts. Also, a variety of stiffener rings or lids are provided to reduce the warpage of the substrate of flip chip packages of prior arts. However, the conventional stiffener rings is to constrain the thermal deformation of the substrate, not bonding to the sides of the chip for constraining the thermal deformation of the chip.

FIG. 1 illustrates a flip chip package using a stiffener ring for reducing the warpage of the flip chip package of prior art. The flip chip package basically comprises a semiconductor chip 10 and a substrate 12, wherein the chip 10 is attached on the substrate 12 through electric conductive bumps 14. Because the bumps 14 are easily damaged during test or application, an underfill 16 is usually dispensed into the gap between the chip and substrate for protecting the bumps from being damaged. An alternative of the underfill 16 is a molded underfill (MUF) as a low cost option. The stiffener ring 22 illustrated in FIG. 1 is attached on the substrate 12 through an adhesive 32. FIG. 1A illustrates a flip chip package using a two-piece lid for further reducing the warpage of the flip chip package of prior art, wherein a cover 20 is attached on the stiffener 22 and the chip 10 through an adhesive 30 and a thermal interface material 34.

FIG. 2 illustrates a flip chip package using a die clip of prior art, in which a die 52 is electrically and mechanically connected on a substrate 58 through bumps 54 and an underfill material 56 and a die clip 50 is attached on the substrate after die attachment and prior to the dispensation of underfill material.

FIG. 3 illustrates a flip chip package using a multi-piece heat spreader 70 and 76 of prior art, wherein a die 72 is electrically and mechanically connected on a substrate 80 through bumps 74 and an underfill material 78, one piece 76 of the multi-piece heat spreader is attached on the substrate 80 after die attachment on substrate and prior to the dispensation of underfill material, and another piece 70 of the multi-piece heat spreader is attached on the substrate 80 after the dispensation of underfill material 78.

The major purpose for flip chip packages to use a stiffener ring or lid is to reduce the warpage of the substrate. However, the conventional method using a stiffener ring or a two-piece lid showed in FIG. 1 and FIG. 1A of prior arts is to mainly constrain the deformation or warpage of the substrate 12. It is seen that there is a space between the sides of the semiconductor chip and the stiffener ring. As a result, the lateral thermal deformation of the chip 32 is not directly constrained by the stiffener ring or the two-piece lid, giving a low efficiency for reducing the warpage of flip chip packages. Another disadvantage using a conventional two-piece lid in flip chip packages is the reliability issues of the adhesive layer 34 between the lid and the top surface of the chip because the edge of the adhesive layer 34 is not enclosed.

The basic concept of the prior arts illustrated in FIG. 2 and FIG. 3 is to use a die clip or one piece of heat spreader for holding the die on the substrate tightly and prevent its movement or warpage during the dispensation and curing of an underfill material, wherein the die clip or the piece of heat spreader is attaching on the substrate and the top surface of the die prior to the dispensation of underfill material. For the prior art illustrated in the FIG. 2, the piece of heat spreader is called a die clip 50, which comprises a top portion and a side portion and has at least one opening on its side portion for the underfill material to get access. For the prior art illustrated in the FIG. 3, a multi-piece heat spreader is used, wherein one piece of the heat spreader 76 which has at least one opening for the underfill material to get access is attached on the substrate and the top surface of the die for preventing the movement of the die during the dispensation and curing of the underfill material. After the dispensation and curing of the underfill material, the second piece of heat spreader 70 is used to close the opening of the first piece of heat spreader. One issue of prior art illustrated in FIG. 2 is that the sides of the die is not enclosed because the die clip has to have one or more openings on its side portion for an underfill material to get access into the gap between the die and the substrate. And one issue of prior art illustrated in FIG. 3 is that other piece of heat spreader has to be used to enclose the openings of the first piece on its side portion, increasing the complexity of the assembly process. Another issue of the prior arts illustrated in FIG. 2 and FIG. 3 is that the die clip or the first piece of the multi-piece heat spreader is to hold the die on the substrate and prevent its movement prior to the dispensation of the underfill material into the gap between the die and the substrate. In fact, it is not necessary to do so because the warpage of a flip chip package mainly develops when the package assembly cools down after curing the underfill material.

The present invention provides a flip chip package using a chip constraint means. The current inventive concept is to reduce the CTE (coefficient of thermal expansion) mismatch by using a chip constraint means to directly constrain the lateral thermal deformation of the chip of the flip chip package. The movement or thermal deformation of the chip is not constrained by the chip constraint means during the dispensation and curing of the underfill material, but the movement or thermal deformation of the chip is constrained when having a temperature change after curing the underfill material. For a flip chip package using a chip constraint means of the present invention, the lateral thermal deformation of the chip is constrained before it causes a serious warpage and stress of the flip chip package. So, the chip constraint means is a way to solve the root cause for the warpage and stress of flip chip packages.

### SUMMARY OF THE INVENTION

The present invention describes a flip chip package using a chip constraint means. The root cause for the warpage and stress of a flip chip package under a temperature change is the CTE (coefficient of thermal expansion) mismatch between the chip and substrate of the flip chip package. The current inventive concept is to reduce the CTE mismatch by using a chip constraint means to constrain the lateral thermal deformation of the chip under a temperature change during the test or application of the flip chip package.

In one preferred embodiment of the present invention, the chip constraint means comprises a chip constraint ring. The chip constraint ring is attached or clipped on the substrate and circumferentially surrounds the sides of the chip prior to dispensing an underfill material into the gap between the chip and the substrate. There is a small gap between the sides of the chip and the chip constraint ring for dispensing an underfill material into the gap between the chip and the substrate. The underfill material also fills the gap between the sides of the chip and the chip constraint ring in the meantime. After curing the underfill material, the chip constraint ring is bonded to the sides of the chip and the substrate, constraining the lateral thermal deformation of the chip and the warpage of the substrate under a temperature change during the test or application of the flip chip package using the chip constraint ring.

In another preferred embodiment of the present invention, the chip constraint means further comprises a chip constraint lid in addition to the chip constraint ring. The chip constraint lid covers and bonds to the chip for further constraining the lateral thermal deformation of the chip. A cavity is defined by the substrate, the chip constraint lid and the chip constraint ring, and the chip is encased inside the cavity. The gaps between the chip and the substrate, between the sides of the chip and the constraint ring are filled by an underfill material, and the gap between the top surface of the chip and the chip constraint lid is filled by an adhesive material which may be the same underfill material. After concurrently curing the underfill material and the adhesive material, the chip constraint ring, the chip constraint lid, the semiconductor chip, and the substrate are bonded together, and the thermal deformation of the semiconductor chip when having a temperature change is well constrained.

It is noted that the chip constraint means does not constrain the movement or thermal deformation of the semiconductor chip before and during the dispensation and curing of the underfill material and the adhesive material. After the curing of the underfill material and the adhesive material, the chip bonds with the chip constraint means, and the movement of the chip starts to be constrained by the chip constraint means thereof. When a high CTE and high modulus material is used for the chip constraint means, the overall CTE of the semiconductor chip and the chip constraint means is to be relatively high, reducing the CTE mismatch between the semiconductor chip and substrate.

For conventional flip chip packages wherein an underfill material is dispensed from the chip sides into the gap between the chip and the substrate, the underfill material may extend outwards from the chip sides on the substrate. So, other electric components mounted on the substrate need to be placed some distance away from the chip sides. Usually, the distance is about 2.5 mm for a large flip chip package. One more benefit of a flip chip package using a chip constraint means of the present invention is that other electric components may be placed much closer to the chip when using a thin chip constraint ring, improving the function performance of the flip chip package.

The inventive concept of present invention for reducing the warpage and stress of flip chip packages is to directly constrain the thermal deformation of the chip by using a chip constraint means to tightly encase the chip. The spirit of the present invention can be easily extended for reducing the warpage and stress of other semiconductor device packages such as flip chip packages with multiple dice. More features and advantages of the present invention are described with reference to the detailed description of the embodiments of the present invention below.

### BRIEF DESCRIPTION OF THE DRAWINGS

FIG. 1 is a schematic cross-sectional view of a flip chip package using a stiffener ring; and FIG. 1A is a schematic cross-sectional view of a flip chip package using a two-piece lid of prior arts.

FIG. 2 is a schematic cross-sectional view of a flip chip package using a die clip of prior art.

FIG. 3 is a schematic cross-sectional view of a flip chip package using a multi-piece heat spreader of prior art.

FIG. 4, FIG. 4A and FIG. 4B are schematic cross-sectional views of a flip chip package using a chip constraint ring which may be a thin ring, or a wide ring with a variety of heights such as the same height as or a bigger height than the chip; and FIG. 4C is a schematic top view of a wide chip constraint ring showing that the wide constraint ring may have other windows for accommodating other electric components mounted on the substrate in additional to the window for accommodating the chip.

FIG. 5, FIG. 5A and FIG. 5B are schematic cross-sectional views of a flip chip package using a bridge-like shape of chip constraint ring which may be attached on or clipped on the substrate.

FIG. 6, FIG. 6A and FIG. 6B are schematic cross-sectional views of a flip chip package using a chip constraint ring and a chip constraint lid comprising a piece of metal, and being placed inside or on the chip constraint ring.

FIG. 7, FIG. 7A and FIG. 7B are schematic cross-sectional or top views of a chip constraint ring, wherein FIG. 7 shows that a thin chip constraint ring may have a variety of cross-sectional shapes, FIG. 7A shows that a chip constraint ring has some bumps on its inner side used as a clipping structure for clipping on the sides of the chip, and FIG. 7B shows a chip constraint ring made by folding a wire type of material, having some bumps and clipping on the sides of the chip.

FIG. 8, FIG. 8A and FIG. 8B are schematic cross-sectional views of a flip chip package using a chip constraint ring and a chip constraint lid comprising a top piece and side walls, wherein FIG. 8A shows that each side wall on each side of the chip constraint lid may be a whole piece or some separate pieces with a comb-like structure, and FIG. 8B shows that the chip constraint lid may further have edge wings extending outwards to the substrate edge.

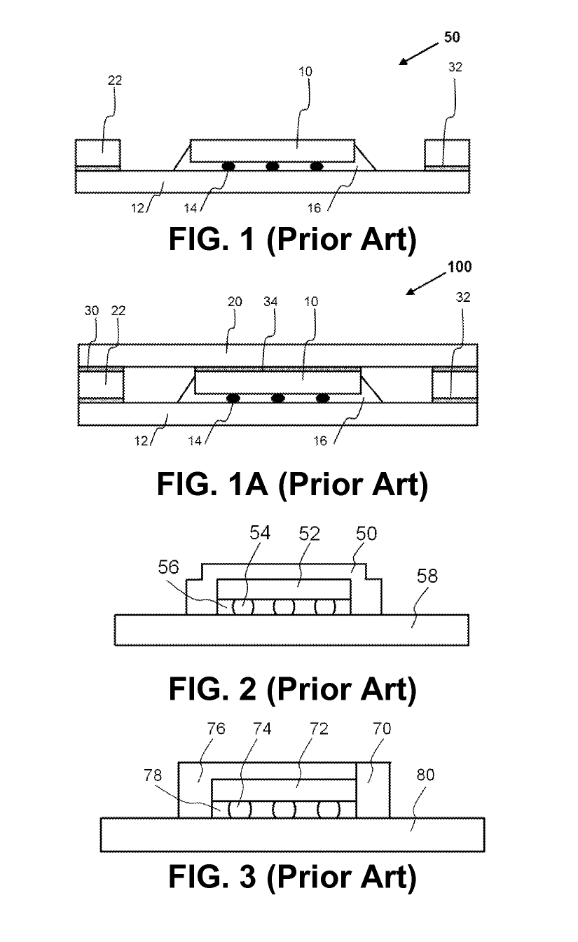

### DETAILED DESCRIPTION OF THE PREFERRED EMBODIMENT

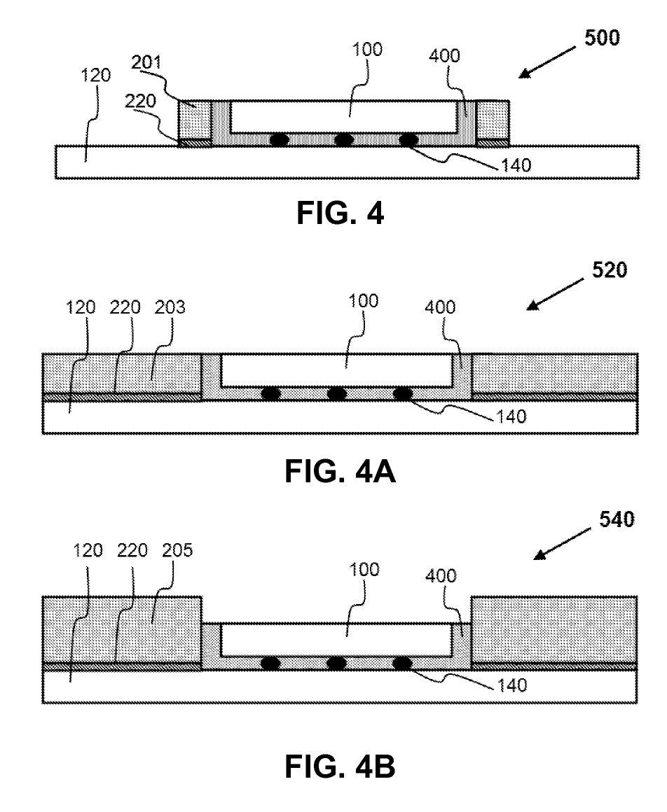

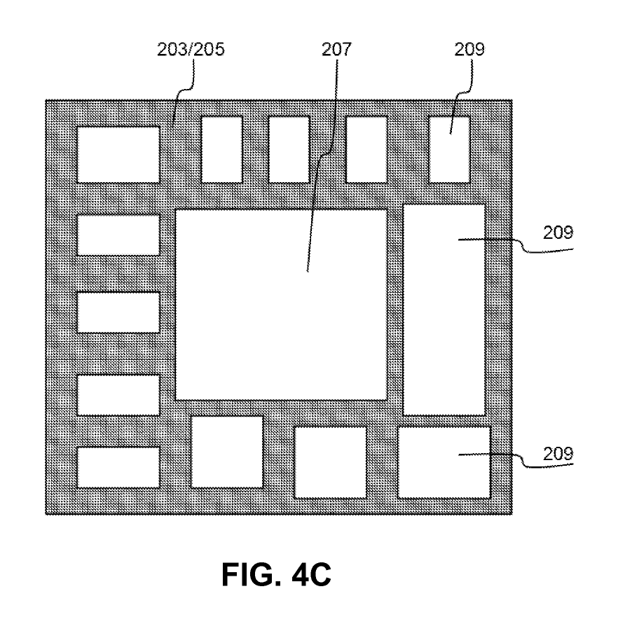

Referring to FIG. 4, a schematic cross-sectional diagram of a flip chip package 500 using a chip constraint ring 201, wherein the chip constraint ring 201 is attached on the substrate 120 through an adhesive material 220, and the underfill material 400 is filled and cured in the gaps between the chip 100 and the chip constraint ring 201 and between the chip 100 and the substrate 120, bonding the chip 100, the chip constraint ring 201 and the substrate 120 together. The width and height of the chip constraint ring 201 may be various. The chip constraint ring 201 showed in FIG. 4 has a small width and the same height as the chip. A small width of chip constraint ring only occupies a small top surface of the substrate near the chip, and other electric components may be placed closer to the chip. FIG. 4A and FIG. 4B show flip chip packages 520 and 540 using chip constraint ring 203 and 205 which have a large width so as to fully cover the substrate. The chip constraint ring 203 has the same height as the chip 100, and the chip constraint ring 205 has a bigger height than the chip 100. A wider and higher chip constraint ring is better for constraining the thermal deformation of the chip and controlling the warpage of the substrate. When other electric components are mounted on the substrate in additional to the chip 100, the chip constraint ring 203 and 205 need to have other windows correspondingly for accommodating the other electric components in additional to the window for accommodating the chip 100. FIG. 4C is a schematic top view of the chip constraint ring 203 and 205, wherein the window 207 is for accommodating the chip 100 and the windows 209 is for accommodating other electric components. The chip constraint ring 201, 203 and 205 may be simply made by punching a metal sheet to form the corresponding windows.

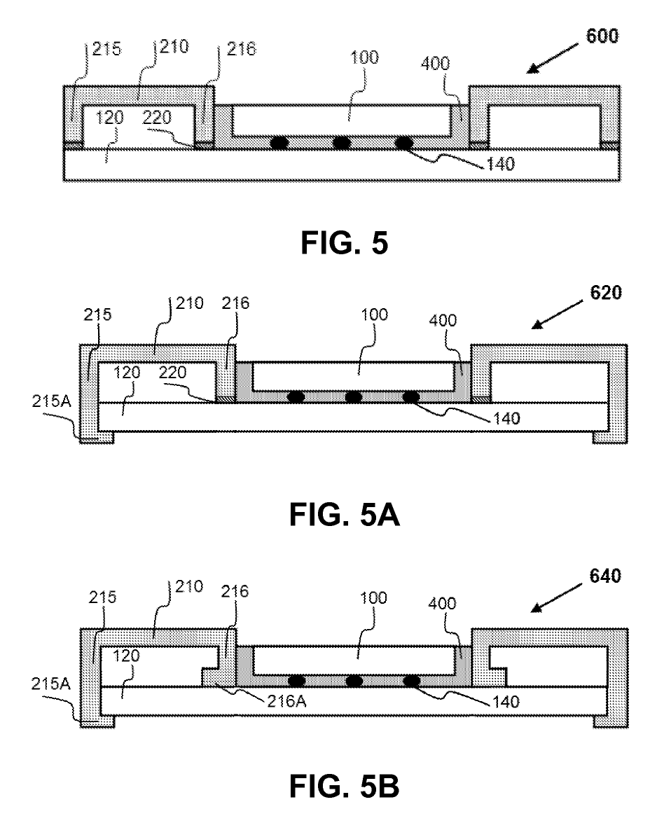

Referring to FIG. 5, a schematic cross-sectional diagram of a flip chip package 600 using a chip constraint ring 210/215/216, wherein the chip constraint ring has a bridge-like cross-section, comprising the top piece 210, the outer walls 215 and the inner walls 216. The outer walls 215 and the inner walls 216 of the bridge-like shape of chip constraint ring are attached on the substrate, only occupying the surface of the substrate 120 near the chip 100 and near the edge of the substrate 120, leaving the top surface of the substrate under the bridge-like shape of chip constraint ring free for mounting other electric components. FIG. 5A shows a flip chip package 620 using a bridge-like shape of chip constraint ring 210/215/215A/216 wherein the outer walls 215 of the bridge-like shape of chip constraint ring have hooks 215A, hooking at the bottom edge of the substrate 120 and the inner walls 216 of the bridge-like shape of chip constraint ring is attached on the substrate 120 and near the chip 100. FIG. 5B shows a flip chip package 640 using a bridge-like shape of chip constraint ring 210/215/215A/216/216A wherein the bridge-like shape of chip constraint ring has a clipping structure for clipping the chip constraint ring on the substrate without using an adhesive material. The clipping structure comprises the outer walls 215 with hooks 215A and the inner walls 216 which may have foot edges 216A. A bridge-like shape of chip constraint ring may be made by folding a metal sheet.

One advantage of a bridge-like shape of chip constraint ring having a clipping structure is that the curing process of the adhesive material for attaching a chip constraint ring on the substrate is avoided. Another advantage of a bridge-like shape of chip constraint ring having a clipping structure is that the clipping structure may apply a force on the substrate bending the substrate upwards, further reducing the downward warpage.

An assembly processes of a flip chip package using a chip constraint ring mainly includes: 1) chip attachment, wherein the chip is mounted on the top surface of the substrate through electrically conductive bumps, 2) mounting of a chip constraint ring, wherein a chip constraint ring is attached or clipped on the substrate or on the sides of the chip and circumferentially surrounds the sides of the chip with a gap between the chip constraint ring and the sides of the chip, 3) underfill dispensation, wherein an underfill material is dispensed from the gap between the chip constraint ring and the sides of the chip to fill the gaps between the chip and the substrate and between the chip constraint ring and the sides of the chip, 4) curing of the underfill material, and 5) solder ball mounting, wherein a plurality of solder balls are mounted on the bottom surface of the substrate for FCBGA (flip chip ball grid array) packages. The process step 2) includes a curing process of the adhesive material if the chip constraint ring is attached on the substrate. It is noted that the curing process of an adhesive material is very time-consuming.

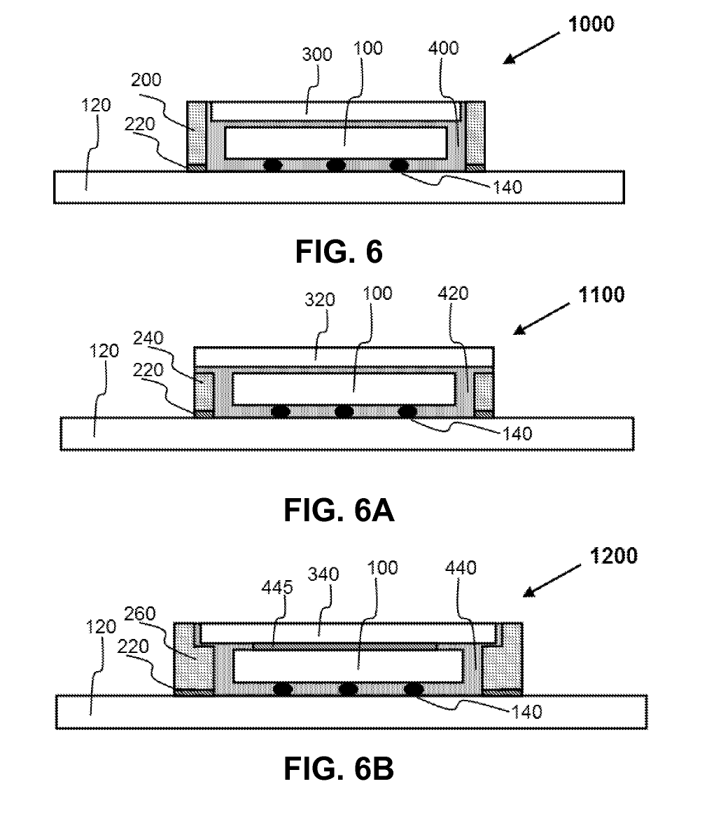

Referring to FIG. 6, a schematic cross-sectional diagram of a flip chip packages 1000 using a chip constraint ring 200 and a chip constraint lid 300 is showed, wherein the chip constraint ring 200 is attached on the substrate 120 through an adhesive material 220, an underfill material 400 is filled and cured in the gaps between the chip 100 and the substrate 120, between the chip constraint ring 200 and the sides of the chip, and between the chip 100 and the chip constraint lid 300. The substrate 120, the chip constraint ring 200 and the chip constraint lid 300 form a cavity encasing the chip 100, and the underfill material 400 mechanically bonds all of them together. The chip constraint ring 200 is higher than the chip 100 so that the chip constraint lid 300 is placed inside the chip constraint ring 200. FIG. 6A shows of a flip chip packages 1100 using a chip constraint ring 240 and a chip constraint lid 320, wherein the chip constraint ring 240 has the same height as the chip 100 so that the chip constraint lid 320 is placed on the chip constraint ring 240. FIG. 6B shows of a flip chip packages 1200 using a chip constraint ring 260 and a chip constraint lid 340, wherein the chip constraint ring 240 has a step shape of cross-section and the chip constraint lid 320 is placed on the step of the chip constraint ring 260. FIG. 6B also shows that the adhesive material 445 for bonding the chip constraint lid to the top surface of the chip may be different from the underfill material 440.

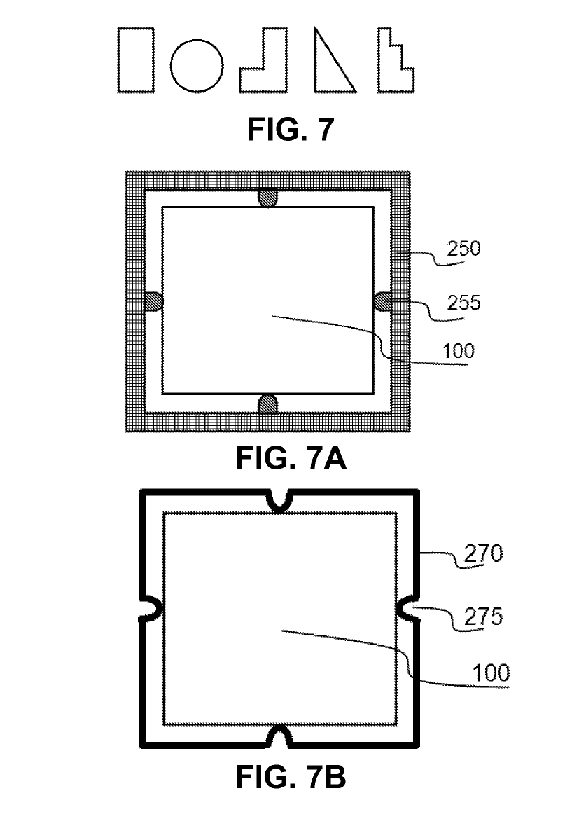

The cross-sectional shape of the chip constraint ring according to one embodiment of the present invention may be various. FIG. 7 shows some examples of the cross-sectional shape of the chip constraint ring, including rectangular shape, circular shape, L-shape, triangular shape, and step shape. Furthermore, the chip constraint ring may have a clipping structure so as to clip the chip constraint ring on the sides of the chip, wherein the chip constraint ring does not need to be attached on the top surface of the substrate using an adhesive material, and only need to contact the top surface of the substrate. FIG. 7A shows an example of a chip constraint ring 250 having a clipping structure, wherein the clipping structure is some bumps 255 on the inner sides of the chip constraint ring, which may be formed by a flexible plastic material or a solder material. The bumps 255 have a dimension so as to clip the chip constraint ring on the sides of the chip 100. FIG. 7B is another example of a chip constraint ring 270 having a bump type of clipping structure 275, wherein the chip constraint ring may be made by folding a wire type of material, such as a metal wire. When a chip constraint ring having a clipping structure is clipped on the sides of the chip, it needs to contact the top surface of the substrate in the meantime. So, when dispensing an underfill material from the gap between the chip constraint ring and the side of the chip, the underfill material will not flow out but into the gap between the chip and the substrate. Because the bumps clipping on the sides of the chip only occupy a small portion of the gap between the chip constraint ring and the side of the chip, the dispensation of an underfill material from the gap is not significantly affected. After curing the underfill material, the chip constraint ring is bonded to the sides of the chip as well as the top surface of the substrate.

A substantial benefit using a chip constraint ring having a clipping structure is that a time-consuming curing process of an adhesive material for attaching a chip constraint ring on the substrate is avoided.

The chip constraint lid showed in FIG. 6, FIG. 6A and FIG. 6B comprises a piece of metal according to one embodiment of the present invention. A potential reliability issue using a piece type of chip constraint lid is a delaminating failure between the chip constraint lid and the chip. For enhancing the bonding between the chip constraint lid and the chip, the piece type of chip constraint lid may have a plurality of small holes. Furthermore, the piece type of chip constraint lid may have a non-uniform thickness with a thicker middle portion and thinner edge portion. The adhesive layer between the top surface of the chip and the piece of lid is to be thicker at the edge of the chip when using the chip constraint lid having a thicker middle portion and thinner edge portion. Because a delaminating failure between the chip constraint lid and the chip more possibly initiate from the chip edge, a thicker adhesive layer at the chip edge is better for reducing the risk of the delaminating failure.

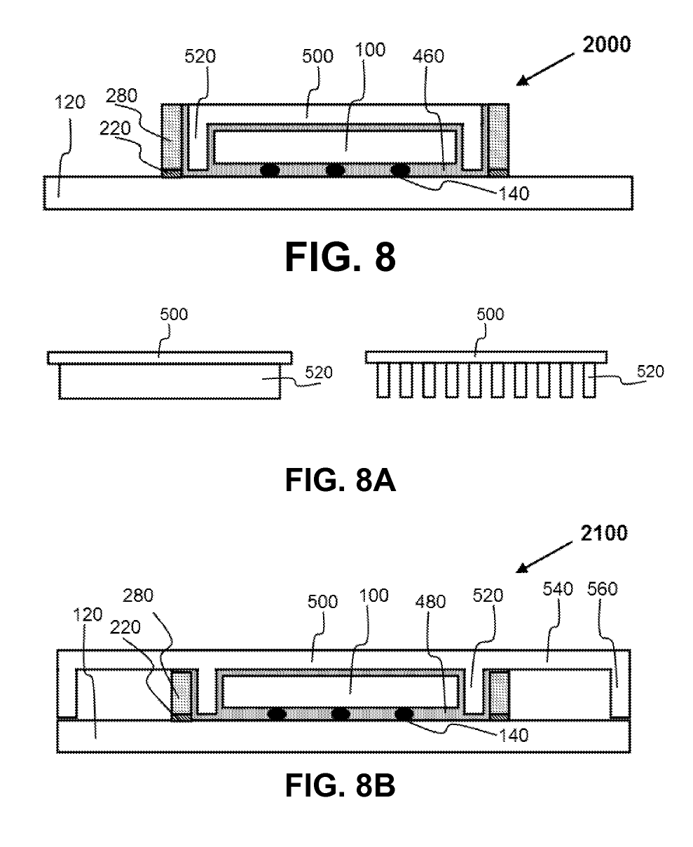

FIG. 8 shows a cross-sectional diagram of a flip chip package 2000 using a chip constraint ring 280 and a chip constraint lid 500/520, wherein the chip constraint lid comprises a top piece 500 and side walls 520. The side walls 520 is inserted into the gap between the chip constraint ring 280 and the sides of the chip 100, and bonded with the chip constraint ring and the sides of the chip. Because the side walls 520 are boned with the chip constraint ring as well as the sides of the chip, the risk of the delaminating failure between the chip constraint lid and the chip may be significantly reduced. FIG. 8A shows that the side wall 520 on each side of the chip constraint lid may comprise a whole piece or some separate pieces with a comb-like structure. A comb-like structure of side wall may have a better bonding with the chip constraint ring and the chip. FIG. 8B shows a cross-sectional diagram of a flip chip package 2100 using a chip constraint ring 280 and a chip constraint lid 500/520/540/560 wherein the chip constraint lid comprises a top piece 500, side walls 520, edge wings 540 and edge supports 560. The edge wings 540 are pieces of metal extending outwards from the top piece 500 of the chip constraint lid for better thermal dissipation. Because the edge wings 540 are flexible, the edge supports 560 is introduced which stand on the top surface of the substrate without bonding to the top surface of the substrate for supporting the edge wings 540. A chip constraint lid may be simply made by folding a metal sheet.

Similar to the piece type of chip constraint lid, the top piece of the chip constraint lid having side walls may have a plurality of small holes; and may have a non-uniform thickness with a thicker middle portion and thinner edge portion for further enhancing the bonding between the chip constraint lid and the chip.

An assembly process of a flip chip package using a chip constraint ring and a chip constraint lid mainly includes: 1) chip attachment, wherein the chip is mounted on the top surface of the substrate through electrically conductive bumps, 2) mounting of a chip constraint ring, wherein a chip constraint ring is attached on the substrate, or clipped on the substrate or clipped on the sides of the chip, and circumferentially surrounds the sides of the chip with a gap between the chip constraint ring and the sides of the chip, 3) underfill dispensation, wherein an underfill material is dispensed from the gap between the chip constraint ring and the sides of the chip to fill the gaps between the chip and the substrate and between the chip constraint ring and the sides of the chip, 4) adhesive dispensation, wherein an adhesive material is dispensed on the top surface of the chip which may be the same underfill material, 5) lid placement, wherein the chip constraint lid is placed over the chip, 6) concurrently curing the underfill and adhesive materials, and 5) solder ball mounting, wherein a plurality of solder balls are mounted on the bottom surface of the substrate for FCBGA (flip chip ball grid array) packages. The process step 2) includes a curing process of the adhesive material if the chip constraint ring is attached on the substrate. It is noted that the curing process of an adhesive material is very time-consuming. So, it is preferred to use a chip constraint ring having a clipping structure.

The flip chip packages using a chip constraint means of the present invention have the following advantages as compared to the conventional flip chip packages using a lid or a heat spreader of prior arts: 1) lower warpage and stress, 2) lower risk of delamination failure for underfill material, 3) lower risk of chip cracking during its testing or operation, 4) lower risk of bump cracking, 5) larger substrate top surface for mounting other components, and 6) easier assembly process.

The inventive concept of the present invention may be used for flip chip packages with multiple chips or multiple stack chips, wherein one or more chip constraint means may be used to encase the multiple chips or multiple stack chips.

Although the present invention is described in some details for illustrative purpose with reference to the embodiments and drawings, it is apparent that many other modifications and variations may be made without departing from the spirit and scope of the present invention.

What is claimed is:

1. A semiconductor chip package, comprising:
a substrate having a top surface and a bottom surface;
a semiconductor chip mounted on the top surface of the substrate through electrically conductive bumps;
a chip constraint ring placed on the top surface of the substrate and circumferentially surrounding the semiconductor chip;
an underfill material filled and cured in the gaps between the semiconductor chip and the substrate and between the sides of the semiconductor chip and the chip constraint ring;
a plurality of solder balls, pins or electric contact lands on the bottom surface of the substrate.

2. The semiconductor chip package of claim 1, wherein the chip constraint ring has a variety of cross-sectional shapes, including rectangular shape, circular shape, triangular shaper, L-shape, and step shape.

3. The semiconductor chip package of claim 1, wherein the chip constraint ring may have some bumps on the inner sides of the chip constraint ring for the chip constraint ring to clip on the sides of the semiconductor chip.

4. The semiconductor chip package of claim 1, wherein the chip constraint ring has a large width so as to fully or substantially cover the top surface of the substrate, and is attached on the top surface of the substrate through an adhesive material.

5. The semiconductor chip package of claim 4, wherein the chip constraint ring may have other windows for accommodating other electric components mounted on the top surface of the substrate in additional to the window for accommodating the semiconductor chip.

6. The semiconductor chip package of claim 1, wherein the chip constraint ring has a bridge-like shape of cross-section, comprising a top piece, outer walls and inner walls; the outer and inner walls are attached on the substrate, occupying the top surfaces of the substrate near the semiconductor chip and near the substrate edge, and leaving the other top surface of the substrate under the bridge-like shape of chip constraint ring free for mounting other electric components.

7. The semiconductor chip package of claim 1, wherein the chip constraint ring has a bridge-like shape of cross-section, comprising a top piece, outer walls and inner walls; each outer wall of the bridge-like shape of chip constraint ring has a hook at its bottom, hooking at the bottom surface of the substrate near the substrate edge so as to clip the chip constraint ring on the substrate without using an adhesive material.

8. The semiconductor chip package of claim 1, further comprising a chip constraint lid, covering the top surface of the semiconductor chip and attached to the semiconductor chip and the chip constraint ring through an adhesive material.

9. The semiconductor chip package of claim 8, wherein the adhesive material for attaching the chip constraint lid to the semiconductor chip may be the same underfill material for filling the gaps between the semiconductor chip and the substrate and between the sides of the semiconductor chip and the chip constraint ring.

10. The semiconductor chip package of claim 8, wherein the chip constraint lid is a piece type of material, including a piece of metal.

11. The semiconductor chip package of claim 10, wherein the piece type of chip constraint lid may have a plurality of small holes; and may have a non-uniform thickness with a thicker middle portion and thinner edge portion.

12. The semiconductor chip package of claim 8, wherein the chip constraint lid comprises a top piece and side walls; the side walls are inserted into the gap between the sides of the semiconductor chip and the chip constraint ring for stronger bonding among the chip constraint lid, the chip constrain ring and the semiconductor chip.

13. The semiconductor chip package of claim 12, wherein the top piece of the chip constraint lid may have a plurality of small holes, may have a non-uniform thickness with a thicker middle portion and thinner edge portion, and may have edge wings extending outwards to the substrate edge.

14. The semiconductor chip package of claim 8, wherein the chip constraint ring has a variety of cross-sectional shapes, including rectangular shape, circular shape, triangular shaper, L-shape, and step shape.

15. The semiconductor chip package of claim 8, wherein the chip constraint ring may have a clipping structure for the chip constraint ring to clip on the sides of the semiconductor chip without using an adhesive material to attach on the top surface of the substrate.

16. The semiconductor chip package of claim 15, wherein the clipping structure of the chip constraint ring is some bumps on the inner sides of the chip constraint ring.

17. The semiconductor chip package of claim 8, wherein the chip constraint ring has a large width so as to fully or substantially cover the top surface of the substrate, and is attached on the top surface of the substrate through an adhesive material.

18. The semiconductor chip package of claim 17, wherein the chip constraint ring may have other windows for accommodating other electric components mounted on the top surface of the substrate in additional to the window for accommodating the semiconductor chip.

19. The semiconductor chip package of claim 8, wherein the chip constraint ring has a bridge-like shape of cross-section, comprising a top piece, outer walls and inner walls; at least the inner walls is attached on the substrate, occupying the top surfaces of the substrate near the semiconductor chip and near the substrate edge, and leaving the other top surface of the substrate under the bridge-like shape of chip constraint ring free for mounting other electric components.

20. The semiconductor chip package of claim 8, wherein the chip constraint ring has a bridge-like shape of cross-section, comprising a top piece, outer walls and inner walls; each outer wall of the bridge-like shape of chip constraint ring has a hook at its bottom, hooking at the bottom surface of the substrate near the substrate edge so as to clip the chip constraint ring on the substrate without using an adhesive no material.
